(19) United States
(12) Patent Application Publication
(10) Pub. No.: US 2025/0246568 A1
(43) Pub. Date: Jul. 31, 2025

(54) METALLIZATION STRUCTURE HAVING AN OUTER METALLIZATION LAYER COMPRISING NICKEL AND PLATINUM LAYERS TO REDUCE INTER-METAL COMPOUND FORMATION

(71) Applicant: RF360 Singapore Pte. Ltd, Singapore (SG)

(72) Inventor: Poh Hoong Yong, Johor Bahru (MY)

(21) Appl. No.: 18/427,155

(22) Filed: Jan. 30, 2024

(51) Int. Cl. H01L 23/00

(52) U.S. Cl. CPC H01L 24/08; H01L 24/03; H01L 24/05; H01L 24/16; H01L 24/81; H01L 2224/0239; H01L 2224/03; H01L 2224/05155; H01L 2224/05669; H01L 2224/08503; H01L 2224/16227; H01L 2224/81447; H01L 2224/81455; H01L 2224/81469; H01L 2224/8181

(57) ABSTRACT

A metallization structure having an outer metallization layer comprising layers of copper (Cu), Nickel (Ni) and Platinum (Pt) to reduce inter-metal compound formation due to high temperature exposure. The layer of copper (Cu) comprises a plurality of interconnects. The metallization structure includes a plurality of interconnect bumps where each bump is coupled to a Cu interconnect of the plurality of Cu interconnects. The Pt layer is adjacent to the Ni layer such that the Pt layer is between the Ni layer and the plurality of interconnect bumps. In this regard, any inter-metal compound (IMC) formation due to the material of the interconnect bumps being coupled (e.g., as a result of a reflow process) to the Cu interconnects is reduced, resulting in a mechanically stronger outer metallization layer.

### BACKGROUND

### I. Field of the Disclosure

The field of the disclosure relates to integrated circuit (IC) dies, and more particularly to design and manufacture of an outer metallization to address inter-metal compound formation.

### II. Background

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that is mounted on and electrically coupled to a package substrate to provide physical support and an electrical interface to the die(s). The package substrate also includes one or more metallization layers that include metal interconnects (e.g., metal traces, metal lines) with vertical interconnect accesses (vias) coupling the metal interconnects together between adjacent metallization layers to provide electrical interfaces between the die(s). The package substrate also includes an outer metallization layer that includes metal interconnects coupled to external metal interconnects (e.g., ball grid array (BGA) interconnects) to provide an external interface between the die(s) in the IC package. The external metal interconnects can also be coupled (e.g., soldered) to traces in a printed circuit board (PCB) to attach the package to the PCB and interface its die(s) with the circuitry of the PCB. The die(s) also includes one or more metallization layers that include metal interconnects (e.g., metal pads, metal traces, metal lines). An outer metallization layer of the one or more metallization layers electrically couples, typically through interconnect balls, the metal interconnects in the die(s) to the metal interconnects (e.g., metal traces) exposed in the outer metallization layer of the package substrate.

### SUMMARY

Aspects disclosed in the detailed description include a metallization structure having an outer metallization layer comprising nickel (Ni) and platinum (Pt) to reduce inter-metal compound (IMC) formation. The metallization structure could be a back-end-of-line (BEOL) interconnect structure of a semiconductor die or part of a package substrate for an IC package as examples. The metallization structure comprises a plurality of metal layers including an outer metallization layer. The outer metallization layer is the last metal layer manufactured on the die and is coupled to interconnect bumps. The outer metallization layer comprises a layer of copper (Cu) comprising a plurality of interconnects for conducting electronic signals, and a plurality of interconnect bumps where each bump is coupled to a Cu interconnect of the plurality of Cu interconnects. The outer metallization layer also comprises a Ni layer between the Cu layer and the plurality of interconnect bumps and a Pt layer adjacent to the Ni layer such that the Pt layer is between the Ni layer and the plurality of interconnect bumps. In this regard, any IMC formation due to the material of the interconnect bumps being coupled (e.g., as a result of a reflow process) to the Cu interconnects is reduced. An IMC can result in a mechanical degradation of the coupling of the Cu interconnects to the interconnect bumps thus risking yield reductions and/or increased interconnect resistance. Also, an increased IMC formation may occur when the metallization structure is repeatedly exposed to high temperatures, for example, coupling an interconnect bump to the outer metallization layer. When the metallization structure is formed on a die and/or a substrate, increased IMC formation may occur due to subsequent exposures during integrated circuit (IC) package assembly, such as attaching dies to an IC package and attaching the IC package to a printed circuit board (PCB). Reducing IMC formation results in a mechanically stronger outer metallization layer.

In this regard in one aspect, a metallization structure comprises an interconnect ball and a plurality of metallization layers each extending in a first direction. An outer metallization layer of the plurality of metallization layers comprises a copper (Cu) interconnect. The Cu interconnect comprises a first surface, a first Cu layer, wherein the interconnect ball is coupled to the first surface. The Cu interconnect also comprises a first nickel (Ni) layer between the first Cu layer and the interconnect ball in a second direction orthogonal to the first direction and a platinum (Pt) layer adjacent to the first Ni layer such that the Pt layer is between the first Ni layer and the interconnect ball in the second direction.

In another aspect, a method for fabricating a metallization structure to reduce inter-metal compound (IMC) formation, comprises forming a plurality of metallization layers including an outer metallization layer, forming a copper (Cu) interconnect in the outer metallization layer. The Cu interconnect has a first surface. Forming the Cu interconnect comprises depositing a first Cu layer to extend in a first direction, depositing a first nickel (Ni) layer adjacent to the first Cu layer to extend in the first direction, and depositing a platinum (Pt) layer adjacent to the first Ni layer to extend in the first direction. The method also comprises coupling an interconnect ball to the first surface of the Cu interconnect.

### BRIEF DESCRIPTION OF THE DRAWINGS

FIG. 1 is a side view of an exemplary IC package, which in this example is a three-dimensional (3D) integrated circuit (IC) (3DIC) package that includes a metallization structure having an outer metallization layer employing nickel (Ni) and platinum (Pt) to reduce inter-metal compound (IMC) formation;

FIG. 2A is a side view of an exemplary metallization structure of the exemplary die shown in FIG. 1 having an outer metallization layer employing Ni and Pt to reduce inter-metal compound IMC formation;

FIG. 2B is a close-up view of a portion of a copper (Cu) interconnect and passivation layer of FIG. 2A employing Ni and Pt to reduce inter-metal compound IMC formation;

FIG. 2C is a close-up view of the portion of the Cu interconnect of FIG. 2A after an interconnect ball has been deposited on a surface of the Cu interconnect and has been exposed to high temperatures forming an IMC;

FIG. 2D is a close-up view of another embodiment of a portion of the Cu interconnect and passivation layer of FIG. 2A employing Ni and Pt to reduce inter-metal compound IMC formation;

FIG. 3A is a side view of a portion of an exemplary substrate shown in FIG. 1 including a metallization structure employing Ni and Pt layers to reduce inter-metal compound IMC formation;

FIG. 3B is a close-up view of a metal pad of FIG. 3A employing Ni and Pt to reduce IMC formation;

FIG. 3C is a close-up view of the metal pad of FIG. 3A after an interconnect ball has been deposited on the surface of the metal pad and has been exposed to high temperatures forming an IMC;

FIG. 4 is a flowchart illustrating an exemplary fabrication process of fabricating a metallization structure, wherein the metallization structure employs Ni and Pt layers to reduce IMC formation including, but not limited to, the exemplary metallization structures in FIGS. 2A-2D and 3A-3C;

FIGS. 5A-5C is a flowchart illustrating another exemplary fabrication process of fabricating a metallization structure, wherein the metallization structure employs Ni and Pt layers to reduce IMC formation including, but not limited to, the exemplary metallization structures in FIGS. 2A-2D and 3A-3C;

FIGS. 6A-6G are exemplary fabrication stages during fabrication of the metallization structure according to the fabrication process in FIGS. 5A-5C;

FIG. 7 is a block diagram of an exemplary processor-based system that can include components deployed in an IC package, wherein the IC package includes a metallization structure(s) employing Ni and Pt layers to reduce IMC formation including, but not limited to, the exemplary metallization structures in FIGS. 2A-2D and 3A-3C and according to the exemplary fabrication processes in FIGS. 4 and 5A-5C; and

FIG. 8 is a block diagram of an exemplary wireless communications device that includes radio-frequency (RF) components deployed in an IC package, wherein the IC package includes a metallization structure(s) employing Ni and Pt layers to reduce IMC formation including, but not limited to, the exemplary metallization structures in FIGS. 2A-2D and 3A-3C and according to the exemplary fabrication processes in FIGS. 4 and 5A-5C.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects. The term “adjacent” as used herein means spatially next to but not necessarily adjoining something as shown in the Figures unless specifically stated otherwise.

Aspects disclosed in the detailed description include a metallization structure having an outer metallization layer comprising nickel (Ni) and platinum (Pt) to reduce inter-metal compound (IMC) formation. The metallization structure could be a back-end-of-line (BEOL) interconnect structure of a semiconductor die or part of a package substrate for an IC package as examples. The metallization structure comprises a plurality of metal layers including an outer metallization layer. The outer metallization layer is the last metal layer manufactured on the die and is coupled to interconnect bumps. The outer metallization layer comprises a layer of copper (Cu) comprising a plurality of interconnects for conducting electronic signals, and a plurality of interconnect bumps where each bump is coupled to a Cu interconnect of the plurality of Cu interconnects. The outer metallization layer also comprises a Ni layer between the Cu layer and the plurality of interconnect bumps and a Pt layer adjacent to the Ni layer such that the Pt layer is between the Ni layer and the plurality of interconnect bumps. In this regard, any IMC formation due to the material of the interconnect bumps being coupled (e.g., as a result of a reflow process) to the Cu interconnects is reduced. An IMC can result in a mechanical degradation of the coupling of the Cu interconnects to the interconnect bumps thus risking yield reductions and/or increased interconnect resistance. Also, an increased IMC formation may occur when the metallization structure is repeatedly exposed to high temperatures, for example, coupling an interconnect bump to the outer metallization layer. When the metallization structure is formed on a die and/or a substrate, increased IMC formation may occur due to subsequent exposures during integrated circuit (IC) package assembly, such as attaching dies to an IC package and attaching the IC package to a printed circuit board (PCB). Reducing IMC formation results in a mechanically stronger outer metallization layer.

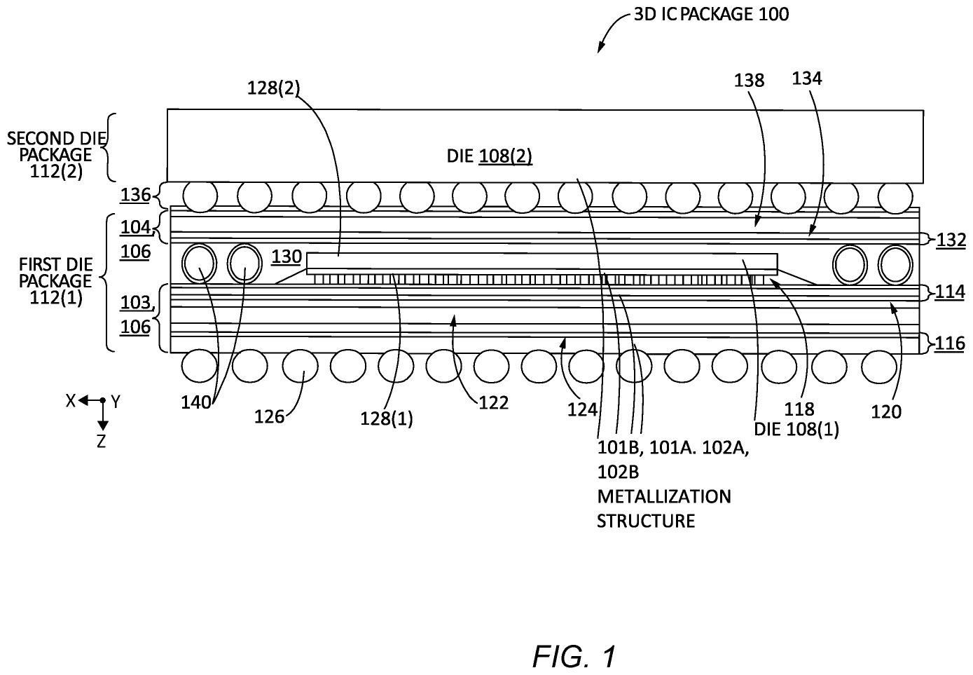

In this regard, FIG. 1 is a side view of an exemplary IC package 100, which in this example is a three-dimensional (3D) integrated circuit (IC) (3DIC) package 100 that includes metallization structures 101A-101B, 102A-102B having an outer metallization layer employing Ni and Pt to reduce IMC formation. The IC package 100 includes a package substrate 103 and an interposer substrate 104. The package substrate 103 and the interposer substrate 104 commonly route signals and power and, for convenience, may both be referred to simply as a substrate 106.

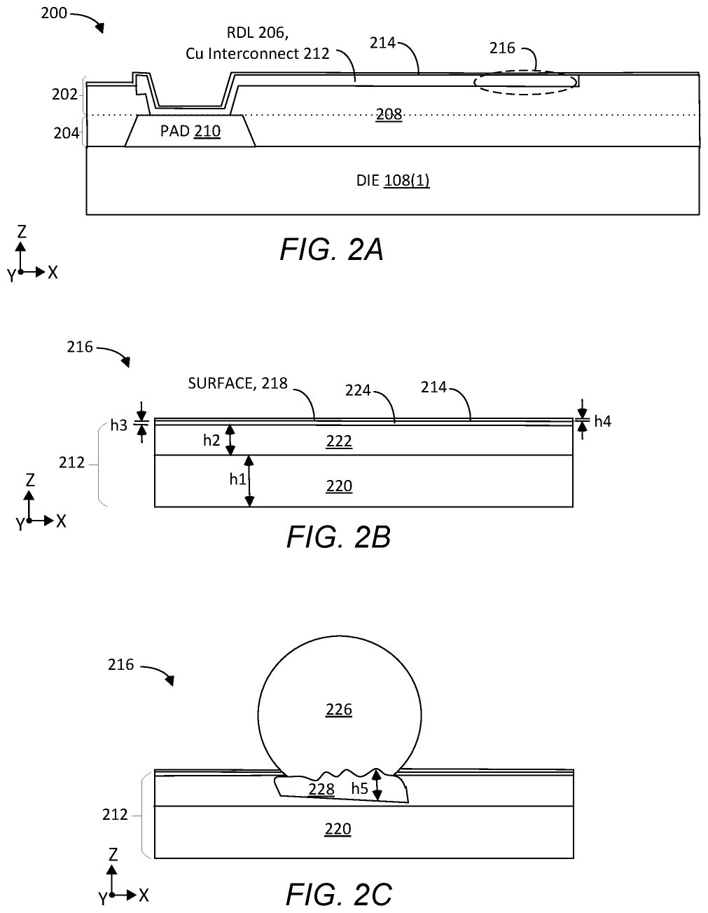

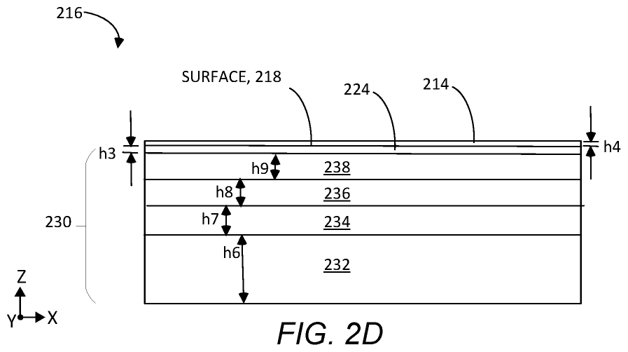

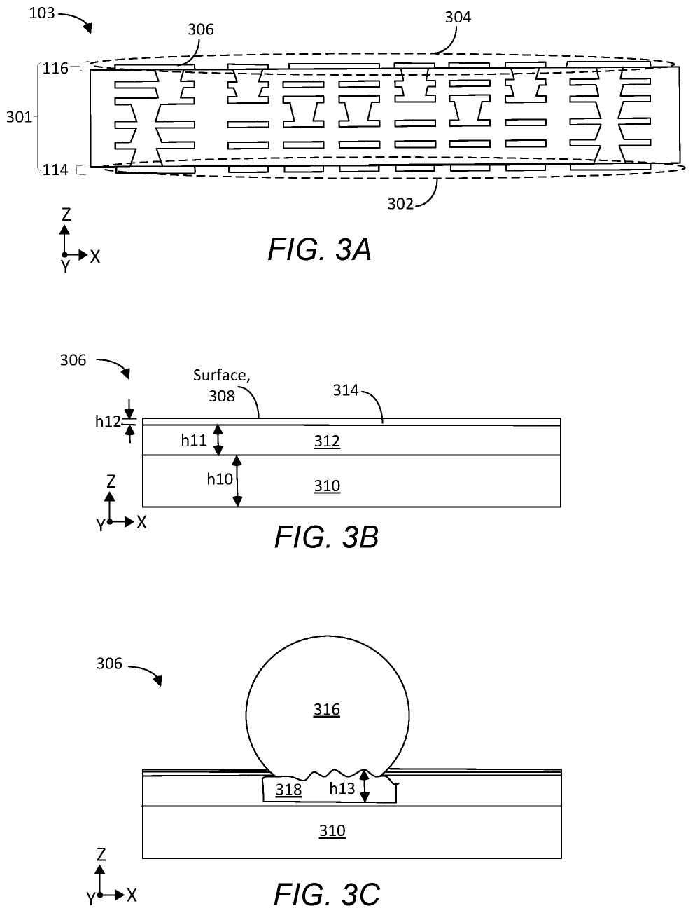

In this example, the IC package 100 includes first and second dies 108(1), 108(2) that are included in respective first and second die packages 112(1), 112(2) that are stacked on top of each other in the vertical direction (Z-axis direction). The first die package 112(1) of the IC package 100 includes the first die 108(1) coupled to the package substrate 103. In this example, the package substrate 103 includes a first, upper and outer metallization layer 114. The first, upper and outer metallization layer 114 provides an electrical interface for signal routing to the first die 108(1). The first die 108(1) is coupled to die interconnects 118 (e.g., raised metal bumps, pillars) that are electrically coupled to metal interconnects 120 in the first, upper and outer metallization layer 114. The first die 108(1) includes the metallization structure 101A which couples the die interconnects 118 to the circuitry within the first die 108(1) and reduces the IMCs formed by the metals in the metallization structure 101A. The metallization structure 101A-11B will be discussed in more detail in connection with FIGS. 2A-2D. The metal interconnects 120 in the first, upper metallization layer 114 are coupled to metal vias 122 (not visible) in the package substrate 103, which are coupled to metal interconnects 124 in a second, bottom and outer metallization layer 116. In this manner, the package substrate 103 provides interconnections between its first and second metallization layers 114 and 116 to provide signal routing to the first die 108(1). Both the first and second metallization layers 114 and 116 will contain a metallization structure 102A and 102B, respectively, and will be discussed in more detail in connection with FIGS. 3A-3D. External interconnects 126 (e.g., ball grid array (BGA) interconnects, a.k.a. bumps) are coupled to the metal interconnects 124 in the second, bottom and outer metallization layer 116 to provide interconnections through the package substrate 103 to the first die 108(1) through the die interconnects 118. In this example, a first, active side 128(1) of the first die 108(1) is adjacent to and coupled to the package substrate 103, and more specifically the first, upper and outer metallization layer 114 of the package substrate 103.

In the exemplary IC package 100 in FIG. 1, an additional optional second die package 112(2) is provided and coupled to the first die package 112(1) to support multiple dies. For example, the first die 108(1) in the first die package 112(1) may include an application processor, and the second die 108(2) may be a memory die, such as a dynamic random access memory (DRAM) die that provides memory support for the application processor. In this regard, in this example, the first die package 112(1) also includes the interposer substrate 104 that is disposed on a package mold 130 encasing the first die 108(1), adjacent to a second, inactive side 128(2) of the first die 108(1). The interposer substrate 104 also includes one or more metallization layers 132 that each include metal interconnects 134 to provide interconnections to the second die 108(2) in the second die package 112(2). The second die package 112(2) is physically and electrically coupled to the first die package 112(1) by being coupled through external interconnects 136 (e.g., solder bumps, BGA interconnects) to the interposer substrate 104. The external interconnects 136 are coupled to the metal interconnects 134 in the interposer substrate 104 through metal vias 138 (not visible). The first die package 112(1) includes vertical interconnects 140 to couple the second die 108(2) to the external interconnects 126 and to the first die 108(1) through the package substrate 103. The second die 108(2) also includes a metallization structure 101B which couples the external interconnects 136 to the circuitry within the second die 108(2) and reduces the IMCs formed by the metals in the metallization structure 101B.

FIG. 2A is a side view of an exemplary metallization structure 200 of the exemplary die 108(1), such as metallization structure 101A shown in FIG. 1 employing Ni and Pt to reduce IMC formation. The exemplary die 108(1) is shown rotated 180° from the way the die 108(1) is shown FIG. 1. The metallization structure 200 includes a plurality of metallization layers 202 and 204 including an outer metallization layer 202. The metallization layers 202, 204 extend in a first, horizontal direction (X-, Y-axes direction). In this example, the outer metallization layer 202 includes a redistribution layer (RDL) 206 and a dielectric 208. The metallization layer 204 includes the dielectric 208 and a metal pad 210 which is electrically coupled to the RDL 206 in a second, vertical direction (Z-axis direction). The RDL 206 includes a plurality of interconnects, including a copper (Cu) interconnect 212. The metal pad 210 is also electrically coupled to circuitry within the die 108(1) (not shown). A passivation layer 214 extends in the first, horizontal direction (X-, Y-axes direction) and is adjacent to the RDL 206 and the Cu interconnect 212. The passivation layer 214 protects the underlying metallization structure from chemical corrosion. A portion 216 of RDL 206 will be discussed in connection with FIGS. 2B and 2C.

FIG. 2B is a close-up view of the portion 216 of the Cu interconnect 212 and passivation layer 214 of FIG. 2A employing Ni and Pt to reduce IMC formation. The Cu interconnect 212 has a surface 218 and includes a Cu layer 220 extending in the first, horizontal direction (X-, Y-axes direction), a first Ni layer 222 disposed directly adjacent to the first Cu layer 220, and a Pt layer 224 disposed directly adjacent to the first Ni layer 222. In other words, the first Ni layer 222 is between the first Cu layer 220 and an interconnect ball (see FIG. 2C) in the second, vertical (Z-axis) direction which is orthogonal to the first, horizontal direction. The Pt layer 224 is between the first Ni layer 222 and the interconnect ball (see FIG. 2C) in the second, vertical direction. The first Cu layer 220 has a thickness, h1, in the range between 1,000-5,000 nanometers (nm) depending on a desired conductivity. If the portion 216 of RDL 206 requires high power handling, thickness, h1, may exceed this range. The first Ni layer 222 has a thickness, h2, in a range between 500-1,000 nm. The Pt layer 224 has a thickness, h3, in a range between 50-150 nm. The passivation layer 214 is disposed directly adjacent to the Pt layer 224 and has a thickness, h4, in the range of 10-100 nm. The ratio of h1 to h2 is between 2 and 5. The ratio of h2 to h3 is between 6-10.

FIG. 2C is a close-up view of the portion 216 of the Cu interconnect 212 and passivation layer 214 of FIG. 2A after an interconnect ball 226 has been deposited on the surface 218 of the Cu interconnect 212 and has been exposed to high temperatures forming an IMC 228. The interconnect ball 226 may include a solder ball comprising tin. The IMC 228 is coupled to the interconnect ball 226 and comprises a diffusion of material of the interconnect ball 226 with material of the first Cu layer 220. In this example, h1 is 1,550 nm, h2 is 400 nm, h3 is 80 nm and the Cu interconnect 212 has been exposed to high temperatures on three separate occasions including reflowing the interconnect ball 226, connecting the die 108(1) to the interposer substrate 104, and connecting the package substrate 103 to a printed circuit board (PCB). In this example the largest thickness, h5, of the IMC 228 is approximately 1,600 nm and bounded within the Ni layer 222 preserving the integrity of the Cu layer 220 and the Cu interconnect 212 as a whole.

FIG. 2D is a close-up view of another embodiment of the portion 216 of a Cu interconnect 230 and the passivation layer 214 of FIG. 2A employing Ni and Pt to reduce IMC formation. Common elements between the Cu interconnect 230 in FIG. 2D and elements of the Cu interconnect 212 in FIG. 2B are shown with common element numbers. The Cu interconnect 230 includes a first Cu layer 232 extending in the first, horizontal direction (X-, Y-axes direction), a first Ni layer 234 disposed directly adjacent to the first Cu layer 232, a second Cu layer 236 disposed directly adjacent to the first Ni layer 234 and between the Pt layer 224 and the first Ni layer 234 in the second, vertical (Z-axis) direction, a second Ni layer 238 disposed directly adjacent to the second Cu layer 236 and between the second Cu layer 236 and the Pt layer 224 in the second, vertical (Z-axis) direction, and the Pt layer 224 disposed directly adjacent to the second Ni layer 238. The first Cu layer 232 has a thickness, h6, of at least in the range between 1,000-5,000 nanometers (nm), depending on a desired conductivity. The first Ni layer 234 has a thickness, h7, in a range between 200-500 nm. The second Cu layer 236 has a thickness, h8, in the range between 500-1,000 nanometers (nm). The second Ni layer 238 has a thickness, h9, in a range between 200-500 nm. The Pt layer 224 has a thickness, h3, in a range between 50-150 nm. The passivation layer 214 is disposed directly adjacent to the Pt layer 224 and has a thickness, h4, of at least, in the range of 10-100 nm. The ratio of h7 to h8 is between 1.5-4.0. The ratio of the h7+h8+h9 to h3 is between 9-18. Please note that a pad, similar to the metal pad 210, may be composed of layers of Cu, Ni, and Pt in the same configuration and the same ratios as the Cu interconnects 212 and 230 if the pad is suitable for bumping, such as, for example, a pad that electrically couples directly to an interconnect ball without an RDL layer, such as the RDL layer 206.

FIG. 3A is a side view of a portion of the package substrate 103 shown in FIG. 1 including a metallization structure, such as metallization structures 102A and 102B, employing Ni and Pt layers to reduce IMC formation. The package substrate 103 is shown rotated 180° from the way the package substrate 103 is shown FIG. 1. The package substrate 103 includes a plurality of metallization layers 301 including outer metallization layers 114 and 116. The outer metallization layers 114, 116 comprise a plurality of Cu interconnects (metal pads, traces) 302, 304, respectively. A metal pad 306 as one of the plurality of Cu interconnects 304 is suitable to be coupled to an interconnect ball and will be described in connection of FIGS. 3B and 3C.

FIG. 3B is a close-up view of the metal pad 306 of FIG. 3A employing Ni and Pt to reduce IMC formation. The metal pad 306 has a surface 308 and includes a first Cu layer 310 extending in a first, horizontal direction (X-, Y-axes direction), a first Ni layer 312 disposed directly adjacent to the first Cu layer 310, and a Pt layer 314 disposed directly adjacent to the first Ni layer 312. In other words, the first Ni layer 312 is between the first Cu layer 310 and an interconnect ball (see FIG. 3C) in a second, vertical direction (Z-axis direction) which is orthogonal to the first direction. The Pt layer 314 is between the first Ni layer 312 and the interconnect ball (see FIG. 3C) in the second, vertical direction. The first Cu layer 310 has a thickness, h10, in the range between 5,000-25,000 nm. The first Ni layer 312 has a thickness, h11, in a range between 500-1,000 nm. The Pt layer 314 has a thickness, h12, of at least 50-150 nm. The ratio of the h11 to h12 is between 6-10.

FIG. 3C is a close-up view of the metal pad 306 of FIG. 3A after an interconnect ball 316 has been deposited on the surface 308 of the metal pad 306 and has been exposed to high temperatures forming an IMC 318. The IMC 318 is coupled to the interconnect ball 316 and comprises a diffusion of material of the interconnect ball 316 with material of the first Cu layer 310. In this example, the metal pad 306 has been exposed to high temperatures. The largest thickness, h13, of the IMC 318 will be similar to h5 given the ranges of Ni and Pt are similar to the ranges disclosed in FIG. 2B.

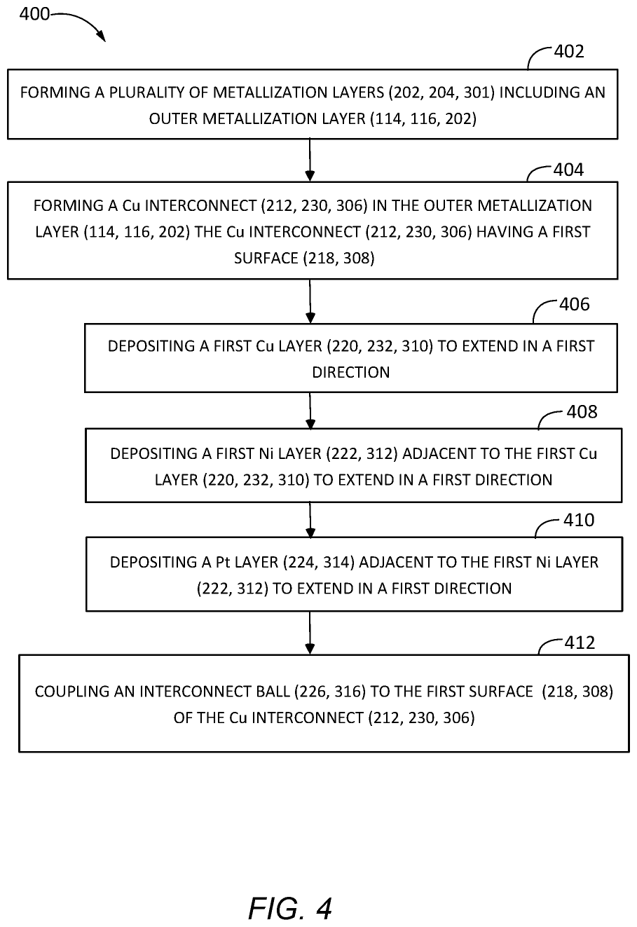

A metallization structure having an outer metallization layer employing Ni and Pt to reduce IMC formation, including, but not limited to, the outer metallization layers including the Cu interconnects 212, 230, 302 and 304 in FIGS. 2A-2D and 3A-3C in the related IC package 100 in FIG. 1 can be fabricated by different fabrication processes. FIG. 4 is a flowchart illustrating an exemplary fabrication process 400 of fabricating a metallization structure including a Cu interconnect such as the Cu interconnects 212, 230, 302 and 304 in FIGS. 2A-2D and 3A-3C in the related IC package 100 in FIG. 1, wherein the outer metallization layer employs Ni and Pt layers to reduce IMC formation, including, but not limited to, in the outer metallization layers in FIGS. 1, 2A-2D, and 3A-3C.

In this regard, a first exemplary step in the fabrication process 400 of FIG. 4 can include forming a plurality of metallization layers 202, 204, 301 including an outer metallization layer 114, 116, 202 (block 402 in FIG. 4). A next step in the fabrication process 400 can include forming a Cu interconnect 212, 230, 306 in the outer metallization layer 114, 116, 202 the Cu interconnect 212, 230, 306 having a first surface 218, 308 (block 404 in FIG. 4). The fabrication process of forming the Cu interconnect 212, 230, 306 includes the following three steps. The first step includes depositing a first Cu layer 220, 232, 310 to extend in a first direction (block 406 in FIG. 4). The next step in the fabrication process of forming the Cu interconnect 212, 230, 306 can include depositing a first Ni layer 222, 312 adjacent to the first Cu layer 220, 232, 310 to extend in the first direction (block 408 in FIG. 4). The next step in the fabrication process of forming the Cu interconnect 212, 230, 306 can include depositing a Pt layer 24, 314) adjacent to the first Ni layer 222, 312 to extend in the first direction (block 410 in FIG. 4). When the previous three steps are performed on a die, they may be performed by placing the die in an evaporation chamber to deposit the three metals. When the previous three steps are performed on a substrate, they may be performed by placing the substrate in an evaporation chamber to deposit the three metals. The next step in the fabrication process 400 can include coupling an interconnect ball 226, 316 to the first surface 218, 308 of the Cu interconnect 212, 230, 306 (block 412 in FIG. 4). This step in the fabrication process may be performed by a different company than the one performing the previous fabrication steps and is usually performed by a packaging company that can deploy bumping services.

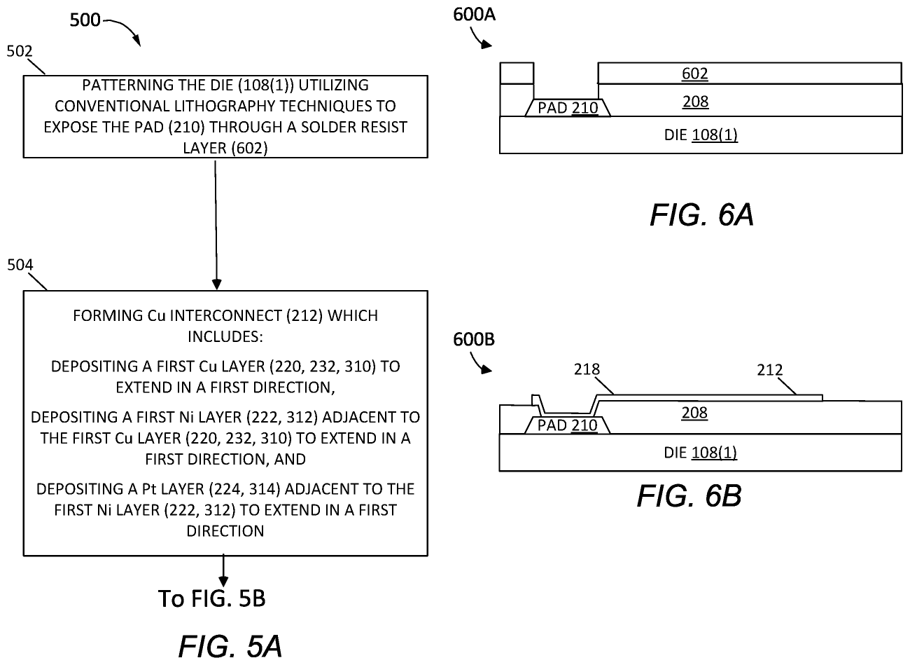

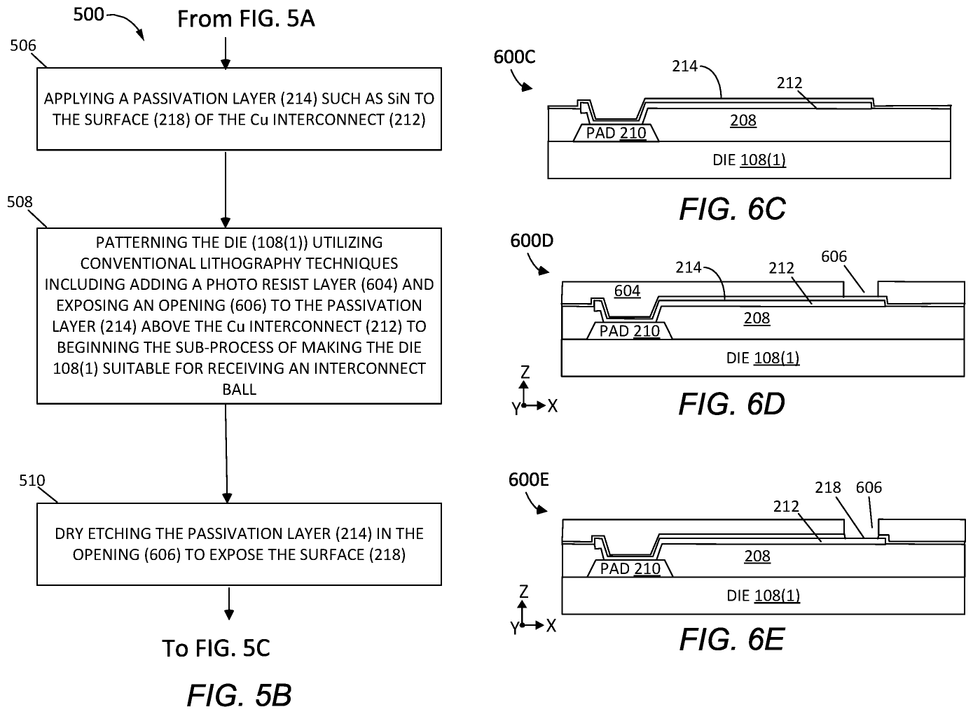

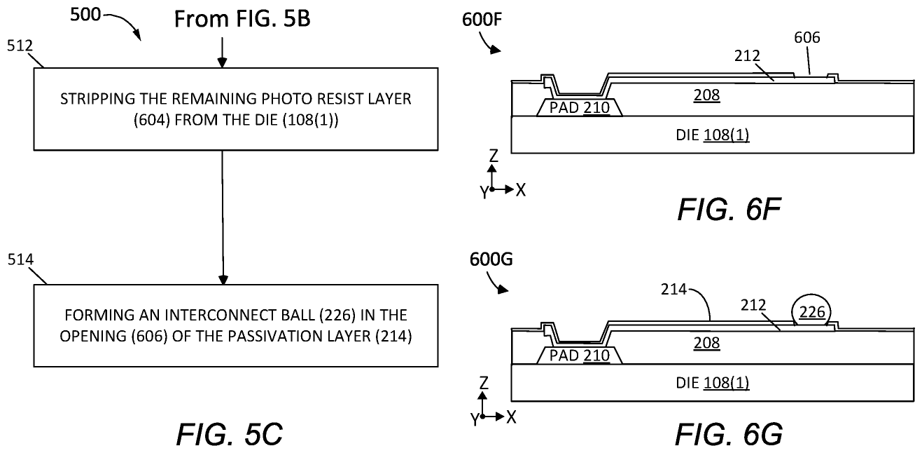

Other fabrication processes can also be employed to fabricate a metallization structure including a Cu interconnect such as the Cu interconnects 212, 230, 302 and 304 in FIGS. 2A-2D and 3A-3C in the related IC package 100 in FIG. 1, wherein the outer metallization layer employs Ni and Pt layers to reduce IMC formation, including, but not limited to, in the outer metallization layers in FIGS. 1, 2A-2D, and 3A-3C. In this regard, FIGS. 5A-5C is a flowchart illustrating another exemplary fabrication process of fabricating a metallization structure including a Cu interconnect such as the Cu interconnects 212, 230, 302 and 304 in FIGS. 2A-2D and 3A-3C in the related IC package 100 in FIG. 1, wherein the outer metallization layer employs Ni and Pt layers to reduce IMC formation, including, but not limited to, the outer metallization layers in FIGS. 1, 2A-2D, and 3A-3C. FIGS. 6A-6H are exemplary fabrication stages during fabrication of the metallization structure according to the fabrication process in FIGS. 5A-5C. The fabrication process 500 as shown in the fabrication stages 600A-600G in FIGS. 6A-6G are in reference to the metallization structure 200 in FIG. 2A and the related IC package 100 in FIG. 1, and thus will be discussed with reference to the metallization structure 200 in FIGS. 2A-2C which is deployed on an existing die such as the die 108(1) in the related IC package 100 in FIG. 1.

In this regard, as shown in fabrication stage 600A in FIG. 6A, an exemplary step in the fabrication process 500 is patterning the die 108(1) utilizing conventional lithography techniques to expose the metal pad 210 through a solder resist layer 602 (block 502 in FIG. 5A). The die 108(1) and the metal pad 210, as shown, has been fabricated utilizing conventional techniques with multiple metallization layers. As shown in fabrication stage 600B in FIG. 6B, a next step in the fabrication process 500 can include forming a Cu interconnect 212. Forming the Cu interconnect 212 includes depositing a first Cu layer 220, 232, 310 to extend in a first direction, depositing a first Ni layer 222, 312 adjacent to the first Cu layer 220, 232, 310 to extend in the first direction, and depositing a Pt layer 224, 314 adjacent to the first Ni layer 222, 312 to extend in the first direction (block 504 in FIG. 5A). For clarity, individual Cu, Ni, and Pt layers are not shown in FIGS. 6B-6G. As shown at fabrication stage 600C in FIG. 6C, a next step in the fabrication process 500 can include applying a passivation layer 214 such as silicon nitride (SiN) to the surface 218 of the Cu interconnect 212 (block 506 in FIG. 5A). As shown at fabrication stage 600D in FIG. 6D, a next step in the fabrication process 500 can include patterning the die 108(1) utilizing conventional lithography techniques including adding a photo resist layer 604 and exposing an opening 606 to the passivation layer 214 above the Cu interconnect 212 to beginning the sub-process of making the die 108(1) suitable for receiving an interconnect ball (block 508 in FIG. 5B). As shown at fabrication stage 600E in FIG. 6E, a next step in the fabrication process 500 can include dry etching the passivation layer 214 in the opening 606 to expose the surface 218 (block 510 in FIG. 5B. As shown at fabrication stage 600F in FIG. 6F, a next step in the fabrication process 500 can include stripping the remaining photo resist layer 604 from the die 108(1) (block 512 in FIG. 5B). As shown at fabrication stage 600G in FIG. 6G, a next step in the fabrication process 500 can include forming an interconnect ball, such as the interconnect ball 226, in the opening 606 of the passivation layer 214 (block 514 in FIG. 5C).

Electronic devices that include an IC package, wherein the IC package includes a metallization structure having an outer metallization layer employing Ni and Pt to reduce IMC formation, including, but not limited to, the outer metallization layers including the Cu interconnects 212, 230, 302 and 304 in FIGS. 2A-2D and 3A-3C in the related IC package 100 in FIG. 1, and can be fabricated according to, but not limited to, the exemplary fabrication processes in FIGS. 4 and 5A-5C, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, and a multicopter.

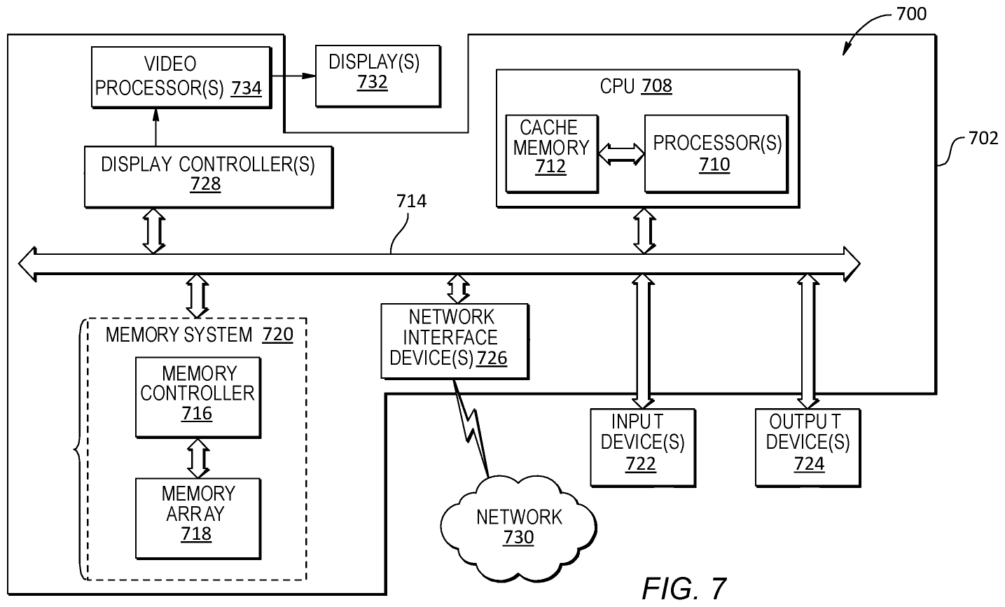

In this regard, FIG. 7 is a block diagram of an exemplary processor-based system that can include components deployed in an IC package, wherein the IC package includes a metallization structure(s) employing Ni and Pt layers to reduce IMC formation including, but not limited to, the exemplary metallization structures in FIGS. 2A-2D and 3A-3C and according to the exemplary fabrication processes in FIGS. 4 and 5A-5C, and according to any exemplary aspects disclosed herein. In this example, the processor-based system 700 may be formed as an IC package 702 such as the IC package 100 in FIG. 1. The processor-based system 700 includes a central processing unit (CPU) 708 that includes one or more processors 710, which may also be referred to as CPU cores or processor cores. The CPU 708 may have cache memory 712 coupled to the CPU 708 for rapid access to temporarily stored data. The CPU 708 is coupled to a system bus 714 and can intercouple master and slave devices included in the processor-based system 700. As is well known, the CPU 708 communicates with these other devices by exchanging address, control, and data information over the system bus 714. For example, the CPU 708 can communicate bus transaction requests to a memory controller 716, as an example of a slave device. Although not illustrated in FIG. 7, multiple system buses 714 could be provided, wherein each system bus 714 constitutes a different fabric.

Other master and slave devices can be connected to the system bus 714. As illustrated in FIG. 7, these devices can include a memory system 720 that includes the memory controller 716 and a memory array(s) 718, one or more input devices 722, one or more output devices 724, one or more network interface devices 726, and one or more display controllers 728, as examples. Each of the memory system(s) 720, the one or more input devices 722, the one or more output devices 724, the one or more network interface devices 726, and the one or more display controllers 728 can be provided in the same or different electronic devices. The input device(s) 722 can include any type of input device, including, but not limited to, input keys, switches, voice processors, etc. The output device(s) 724 can include any type of output device, including, but not limited to, audio, video, other visual indicators, etc. The network interface device(s) 726 can be any device configured to allow exchange of data to and from a network 730. The network 730 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 726 can be configured to support any type of communications protocol desired.

The CPU 708 may also be configured to access the display controller(s) 728 over the system bus 714 to control information sent to one or more displays 732. The display controller(s) 728 sends information to the display(s) 732 to be displayed via one or more video processor(s) 734, which process the information to be displayed into a format suitable for the display(s) 732. The display controller(s) 728 and video processor(s) 734 can be included as ICs in the same or different electronic devices, and in the same or different electronic devices containing the CPU 708, as an example. The display(s) 732 can include any type of display, including, but not limited to, a cathode ray tube (CRT), a liquid crystal display (LCD), a plasma display, a light emitting diode (LED) display, etc.

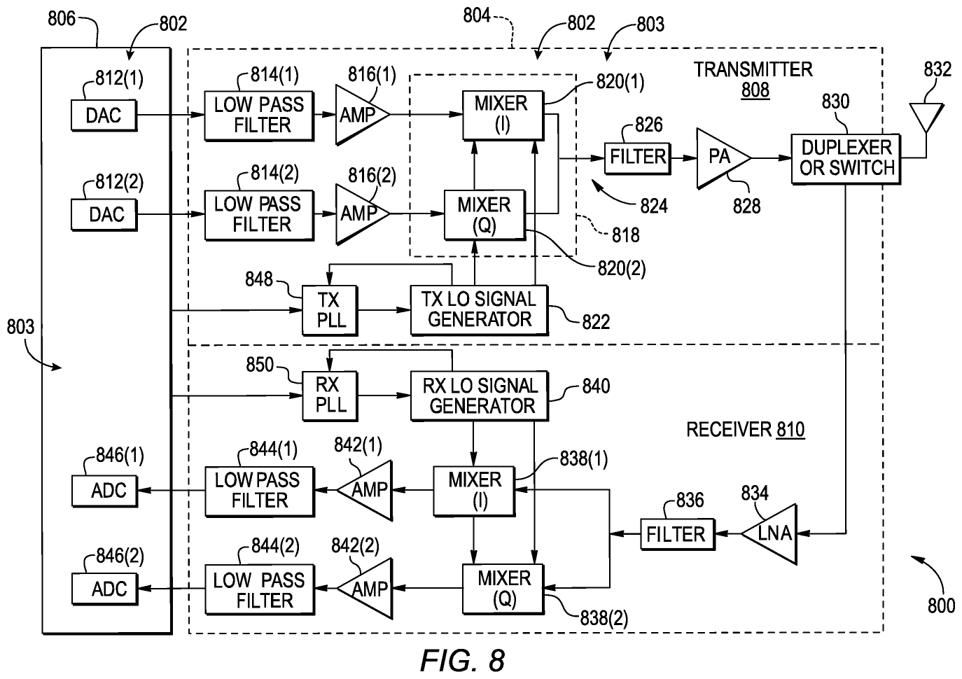

FIG. 8 illustrates an exemplary wireless communications device 800 that includes radio-frequency (RF) components formed from one or more ICs 802, wherein any of the ICs 802 can be deployed in an IC package 803 wherein the IC package 803 includes a metallization structure(s) employing Ni and Pt layers to reduce IMC formation including, but not limited to, the exemplary metallization structures in FIGS. 2A-2D and 3A-3C and according to the exemplary fabrication processes in FIGS. 4 and 5A-5C, and according to any exemplary aspects disclosed herein. The wireless communications device 800 may include or be provided in any of the above-referenced devices, as examples. As shown in FIG. 8, the wireless communications device 800 includes a transceiver 804 and a data processor 806. The data processor 806 may include a memory to store data and program codes. The transceiver 804 includes a transmitter 808 and a receiver 810 that support bi-directional communications. In general, the wireless communications device 800 may include any number of transmitters 808 and/or receivers 810 for any number of communication systems and frequency bands. All or a portion of the transceiver 804 may be implemented on one or more analog ICs, RF ICs (RFICs), mixed-signal ICs, etc.

The transmitter 808 or the receiver 810 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage, and then from IF to baseband in another stage for the receiver 810. In the direct-conversion architecture, a signal is frequency-converted between RF and baseband in one stage. The super-heterodyne and direct-conversion architectures may use different circuit blocks and/or have different requirements. In the wireless communications device 800 in FIG. 8, the transmitter 808 and the receiver 810 are implemented with the direct-conversion architecture.

In the transmit path, the data processor 806 processes data to be transmitted and provides I and Q analog output signals to the transmitter 808. In the exemplary wireless communications device 800, the data processor 806 includes digital-to-analog converters (DACs) 812(1), 812(2) for converting digital signals generated by the data processor 806 into the I and Q analog output signals (e.g., I and Q output currents) for further processing.

Within the transmitter 808, lowpass filters 814(1), 814(2) filter the I and Q analog output signals, respectively, to remove undesired signals caused by the prior digital-to-analog conversion. Amplifiers (AMPs) 816(1), 816(2) amplify the signals from the lowpass filters 814(1), 814(2), respectively, and provide I and Q baseband signals. An upconverter 818 upconverts the I and Q baseband signals with I and Q transmit (TX) local oscillator (LO) signals through mixers 820(1), 820(2) from a TX LO signal generator 822 to provide an upconverted signal 824. A filter 826 filters the upconverted signal 824 to remove undesired signals caused by the frequency up-conversion as well as noise in a receive frequency band. A power amplifier (PA) 828 amplifies the upconverted signal 824 from the filter 826 to obtain the desired output power level and provides a transmit RF signal. The transmit RF signal is routed through a duplexer or switch 830 and transmitted via an antenna 832.

In the receive path, the antenna 832 receives signals transmitted by base stations and provides a received RF signal, which is routed through the duplexer or switch 830 and provided to a low noise amplifier (LNA) 834. The duplexer or switch 830 is designed to operate with a specific receive (RX)-to-TX duplexer frequency separation, such that RX signals are isolated from TX signals. The received RF signal is amplified by the LNA 834 and filtered by a filter 836 to obtain a desired RF input signal. Down-conversion mixers 838(1), 838(2) mix the output of the filter 836 with I and Q RX LO signals (i.e., LO_I and LO_Q) from an RX LO signal generator 840 to generate I and Q baseband signals. The I and Q baseband signals are amplified by AMPs 842(1), 842(2) and further filtered by lowpass filters 844(1), 844(2) to obtain I and Q analog input signals, which are provided to the data processor 806. In this example, the data processor 806 includes analog-to-digital converters (ADCs) 846(1), 846(2) for converting the analog input signals into digital signals to be further processed by the data processor 806.

In the wireless communications device 800 of FIG. 8, the TX LO signal generator 822 generates the I and Q TX LO signals used for frequency up-conversion, while the RX LO signal generator 840 generates the I and Q RX LO signals used for frequency down-conversion. Each LO signal is a periodic signal with a particular fundamental frequency. A TX phase-locked loop (PLL) circuit 848 receives timing information from the data processor 806 and generates a control signal used to adjust the frequency and/or phase of the TX LO signals from the TX LO signal generator 822. Similarly, an RX PLL circuit 850 receives timing information from the data processor 806 and generates a control signal used to adjust the frequency and/or phase of the RX LO signals from the RX LO signal generator 840.

Those of skill in the art will further appreciate that the various illustrative logical blocks, modules, circuits, and algorithms described in connection with the aspects disclosed herein may be implemented as electronic hardware, instructions stored in memory or in another computer readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:

1. A metallization structure, comprising:
an interconnect ball; and
a plurality of metallization layers each extending in a first direction;
an outer metallization layer of the plurality of metallization layers comprising a copper (Cu) interconnect, the Cu interconnect comprising:
   a first surface;
   a first Cu layer;
   the interconnect ball coupled to the first surface;
   a first nickel (Ni) layer between the first Cu layer and the interconnect ball in a second direction orthogonal to the first direction; and
   a platinum (Pt) layer adjacent to the first Ni layer such that the Pt layer is between the first Ni layer and the interconnect ball in the second direction.

2. The metallization structure of clause 1, further comprising:
a second Cu layer between the Pt layer and the first Ni layer in the second direction; and
a second Ni layer between the second Cu layer and the Pt layer in the second direction.

3. The metallization structure of clause 1 or 2, further comprising:
an inter-metal compound (IMC) coupled to the interconnect ball, the IMC comprising a diffusion of material of the interconnect ball with material of the Cu interconnect.

4. The metallization structure of any of clauses 1-3, wherein:
the first Cu layer has a first thickness extending in the second direction orthogonal to the first direction;
the first Ni layer has a second thickness extending in the second direction; and
the Pt layer has a third thickness extending in the second direction.

5. The metallization structure of clause 4, wherein the first thickness is in a range between 1,000-5,000 nanometers (nm).

6. The metallization structure of clause 4 or 5, wherein the second thickness is in a range between 500-1,000 nm.

7. The metallization structure of any of clauses 4-6, wherein the third thickness is in a range between 50-150 nm.

8. The metallization structure of any of clauses 4-7, wherein a ratio of the first thickness to the second thickness is between 2-5.

9. The metallization structure of any of clauses 4-8, wherein a ratio of the second thickness to the third thickness is between 6-10.

10. The metallization structure of clause 1, further comprising:
a substrate including a metal pad, the substrate coupled to the Cu interconnect through the interconnect ball.

11. The metallization structure of clause 10, wherein the substrate comprises:
the metal pad comprising:
   a second Cu layer;
   a second Ni layer disposed adjacent to the second Cu layer; and
   a second Pt layer disposed adjacent to the second Ni layer.

12. The metallization structure of any of clauses 1-11 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics systems; and a multicopter.

13. A method for fabricating a metallization structure to reduce inter-metal compound (IMC) formation, comprising:
forming a plurality of metallization layers including an outer metallization layer;
forming a copper (Cu) interconnect in the outer metallization layer, the Cu interconnect having a first surface, forming the Cu interconnect comprising:
   depositing a first Cu layer to extend in a first direction;
   depositing a first nickel (Ni) layer adjacent to the first Cu layer to extend in the first direction; and
   depositing a platinum (Pt) layer adjacent to the first Ni layer to extend in the first direction; and
coupling an interconnect ball to the first surface of the Cu interconnect.

14. The method of clause 13, further comprising:
depositing a second Cu layer between the Pt layer and the first Ni layer in the second direction orthogonal to the first direction; and
depositing a second Ni layer between the second Cu layer and the Pt layer in the second direction.

15. The method of clause 13 or 14, further comprising:
forming an IMC coupled to the interconnect ball, the IMC comprising a diffusion of material of the interconnect ball with material of the first Cu layer.

16. The method of any of clauses 13-15, wherein:
the first Cu layer has a first thickness extending in the second direction;
the first Ni layer has a second thickness extending in the second direction; and
the Pt layer has a third thickness extending in the second direction.

17. The method of clause 16, wherein the first thickness is in a range between 1,000-5,000 nanometers (nm).

18. The method of clause 16 or 17, wherein the second thickness is in a range between 500-1,000 nm.

19. The method of any of clauses 16-18, wherein the third thickness is in a range between 50-150 nm.

20. The method of any of clauses 16-19, wherein a ratio of the second thickness to the third thickness is between 6-10.

What is claimed is:

1. A metallization structure, comprising:
an interconnect ball; and
a plurality of metallization layers each extending in a first direction;
an outer metallization layer of the plurality of metallization layers comprising a copper (Cu) interconnect, the Cu interconnect comprising:
a first surface;
a first Cu layer;
the interconnect ball coupled to the first surface;
a first nickel (Ni) layer between the first Cu layer and the interconnect ball in a second direction orthogonal to the first direction; and
a platinum (Pt) layer adjacent to the first Ni layer such that the Pt layer is between the first Ni layer and the interconnect ball in the second direction.

2. The metallization structure of claim 1, further comprising:
a second Cu layer between the Pt layer and the first Ni layer in the second direction; and
a second Ni layer between the second Cu layer and the Pt layer in the second direction.

3. The metallization structure of claim 1, further comprising:
an inter-metal compound (IMC) coupled to the interconnect ball, the IMC comprising a diffusion of material of the interconnect ball with material of the Cu interconnect.

4. The metallization structure of claim 1, wherein:
the first Cu layer has a first thickness extending in the second direction orthogonal to the first direction;
the first Ni layer has a second thickness extending in the second direction; and
the Pt layer has a third thickness extending in the second direction.

5. The metallization structure of claim 4, wherein the first thickness is in a range between 1,000-5,000 nanometers (nm).

6. The metallization structure of claim 5, wherein the second thickness is in a range between 500-1,000 nm.

7. The metallization structure of claim 5, wherein the third thickness is in a range between 50-150 nm.

8. The metallization structure of claim 4, wherein a ratio of the first thickness to the second thickness is between 2-5.

9. The metallization structure of claim 4, wherein a ratio of the second thickness to the third thickness is between 6-10.

10. The metallization structure of claim 1, further comprising:
a substrate including a metal pad, the substrate coupled to the Cu interconnect through the interconnect ball.

11. The metallization structure of claim 10, wherein the substrate comprises:
the metal pad comprising:
a second Cu layer;
a second Ni layer disposed adjacent to the second Cu layer; and
a second Pt layer disposed adjacent to the second Ni layer.

12. The metallization structure of claim 1 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics systems; and a multicopter.

13. A method for fabricating a metallization structure to reduce inter-metal compound (IMC) formation, comprising:
forming a plurality of metallization layers including an outer metallization layer;
forming a copper (Cu) interconnect in the outer metallization layer, the Cu interconnect having a first surface, forming the Cu interconnect comprising:
depositing a first Cu layer to extend in a first direction;
depositing a first nickel (Ni) layer adjacent to the first Cu layer to extend in the first direction; and
depositing a platinum (Pt) layer adjacent to the first Ni layer to extend in the first direction; and
coupling an interconnect ball to the first surface of the Cu interconnect.

14. The method of claim 13, further comprising:
depositing a second Cu layer between the Pt layer and the first Ni layer in the second direction orthogonal to the first direction; and
depositing a second Ni layer between the second Cu layer and the Pt layer in the second direction.

15. The method of claim 13, further comprising:
forming an IMC coupled to the interconnect ball, the IMC comprising a diffusion of material of the interconnect ball with material of the first Cu layer.

16. The method of claim 13, wherein:
the first Cu layer has a first thickness extending in the second direction;
the first Ni layer has a second thickness extending in the second direction; and
the Pt layer has a third thickness extending in the second direction.

17. The method of claim 16, wherein the first thickness is in a range between 1,000-5,000 nanometers (nm).

18. The method of claim 17, wherein the second thickness is in a range between 500-1,000 nm.

19. The method of claim 17, wherein the third thickness is in a range between 50-150 nm.

20. The method of claim 16, wherein a ratio of the second thickness to the third thickness is between 6-10.
